(19) United States
(12) Patent Application Publication
(10) Pub. No.: US 2015/0255465 A1
(43) Pub. Date: Sep. 10, 2015

(54) SEMICONDUCTOR DEVICE, AND MANUFACTURING METHOD FOR SAME

(71) Applicant: Masahiro YOKOMICHI, Chuo-ku, Tokyo (JP)

(72) Inventor: Masahiro Yokomichi, Tokyo (JP)

(21) Appl. No.: 14/438,781

(22) PCT Filed: Oct. 11, 2013
(86) PCT No.: PCT/JP2013/077698

§ 371 Date: Apr. 27, 2015

(30) Foreign Application Priority Data
Oct. 31, 2012 (JP) 2012-239961

(51) Int. Cl. H01L 27/108; H01L 23/532; H01L 21/3205; H01L 23/528; H01L 21/768; H01L 21/3213

(52) U.S. Cl. CPC H01L 27/10855; H01L 21/76802; H01L 21/76877; H01L 21/32139; H01L 21/76886; H01L 21/76837; H01L 27/10823; H01L 21/76897; H01L 21/32053; H01L 23/528; H01L 23/53271; H01L 23/53209

(57) ABSTRACT

This method for manufacturing a semiconductor device comprises: a step for forming a first groove (51) that extends in a prescribed direction in a first insulating layer (25) on a semiconductor substrate (1); a step for forming an electrically conductive embedded layer (127) in the first groove; a step for forming a first and second plug (27b, 27c) by dividing the embedded layer in a prescribed direction; a step for forming a first conductive film (55), having lower resistance than the embedded layer, on the exposed side surfaces of the first and second plugs; a step for embedding a second insulating layer (29) in a second groove that is located between the first conductive films of the first and second plugs; and a step for forming a second conductive film (37), having lower resistance than the embedded layer, on the exposed top surfaces of the first and second plugs.

### TECHNICAL FIELD

The present invention relates to a semiconductor device and a method for manufacturing the same.

### BACKGROUND ART

Patent literature article 1 discloses one configuration example of a DRAM (Dynamic Random Access Memory), as a semiconductor device.

The configuration of a memory cell in a DRAM will be described with reference to FIG. 1. FIG. 1 is a cross-sectional view illustrating one configuration example of a related semiconductor device.

Word lines WL10a to WL10c connected to gate electrodes of MOS (Metal Oxide Semiconductor) transistors, and a dummy word line DWL which isolates active regions, are provided in a semiconductor substrate 1. Impurity-diffused layers 19a to 19c which form one electrode, from the source electrode and the drain electrode, of the MOS transistor are connected to capacitors 39 by way of capacitor contact plugs 27a to 27c and capacitor contact pads 32.

Impurity-diffused layers (which are not shown in the drawing) which form the other electrode, from the source electrode and the drain electrode, of the MOS transistor are connected to bit lines (which are not shown in the drawing). Although not shown in the drawing, the bit lines extend in a direction that is orthogonal to the longitudinal direction of the word lines WL10a to WL10c. The capacitor contact pads 32 are formed from a titanium nitride film 30 and a tungsten film 31. The capacitors 39 are formed from a lower electrode 34, a capacitative insulating film 35 and an upper electrode 36.

As illustrated in FIG. 1, the capacitor contact plug 27b and the capacitor contact plug 27c are disposed opposing each other, sandwiching a capacitor contact isolating and insulating film 29 in a groove having an inverted tapered shape, provided in an SOD (Spin On Dielectric) film 25. Cobalt silicide 37 is formed on the upper surfaces of the capacitor contact plugs 27b and 27c.

By forming the cobalt silicide 37 on the upper surfaces of the capacitor contact plugs 27a to 27c, the contact resistance between the capacitor contact plugs 27a to 27c and the capacitor contact pads 32 is reduced. The capacitor contact plugs 27b and 27c are disposed opposing one another in the same groove, with the interposition of an insulating layer, and such a pair of plugs is therefore referred to hereinafter as a ‘twin plug’.

A method of manufacturing the semiconductor device illustrated in FIG. 1 will now be described. Here, detailed descriptions of the step illustrated in FIG. 1 to the step illustrated in FIG. 12 in patent literature article 1 are omitted, and the method of forming the twin plugs will mainly be described in detail.

FIG. 2A to FIG. 5C are cross-sectional views used to describe the method of manufacturing the semiconductor device illustrated in FIG. 1.

A liner film 56 and a silicon nitride film are formed by CVD (Chemical Vapor Deposition) in such a way as to cover the surfaces of bit lines (which are not shown in the drawings) and a semiconductor substrate 1. An SOD film 25, which is a coating film, is then deposited in such a way as to fill spaces between the bit lines (which are not shown in the drawings), after which annealing is carried out in a high-temperature steam (H₂O) atmosphere, reforming the SOD film 25 to a solid film. The SOD film 25 is planarized by CMP (Chemical and Mechanical Polishing) until the upper surface of the liner film 56 is exposed, after which a silicon dioxide film is formed as a cap silicon dioxide film 26 by CVD, to cover the surface of the SOD film 25. Further, a masking polysilicon film 21 is formed by CVD on the cap silicon dioxide film 26 (FIG. 2A).

Next, using photolithography and dry etching, grooves having an inverted tapered shape are formed in the laminated film comprising the liner film 56, the SOD film 25, the cap silicon dioxide film 26 and the masking polysilicon film 21. These grooves constitute capacitor contact holes 51 for forming the capacitor contact plugs 27a to 27c. More specifically, the following procedure is performed.

A capacitor contact hard mask is formed from the cap silicon dioxide film 26 and the masking polysilicon film 21 by patterning using lithography and etching. The capacitor contact hard mask is configured to have a pattern of openings in the form of lines extending in the same direction as the longitudinal direction of the word lines WL10a to WL10d illustrated in FIG. 1. Next, by etching the SOD film 25 and the liner film 56 as far as the substrate surface using dry etching, with the capacitor contact hard mask as a mask, the capacitor contact holes 51 are formed penetrating through the laminated film. The semiconductor substrate 1 is exposed in the sections in which the capacitor contact holes 51 and active regions 13 intersect.

A silicon nitride film is then formed by CVD and the silicon nitride film is etched back, thereby forming side walls 23 on the sidewalls of the laminated film, as illustrated in FIG. 2B.

Next, CVD is used to fill the interior of the capacitor contact holes 51 with a polysilicon film doped with an n-type electrically-conductive impurity such as phosphorus. The polysilicon film is then etched back in such a way as to make the upper surface of the polysilicon film lower than the upper surface of the laminated film, to form polysilicon plugs 127, as illustrated in FIG. 3A. N-type impurity-diffused layers 19a to 19c are formed in the capacitor contact holes 51, in the vicinity of the surface of the semiconductor substrate 1, by means of the n-type electrically-conductive impurity with which the polysilicon plugs 127 have been doped. The impurity-diffused layers 19a to 19c function as source electrodes or drain electrodes of MOS transistors.

Next, as illustrated in FIG. 3B, a silicon nitride film 28 is formed in such a way as to cover the polysilicon plugs 127 formed in the capacitor contact holes 51. The silicon nitride film 28 is then etched back to form side walls 28a, as illustrated in FIG. 4A. The polysilicon plugs 127 are then dry etched, using the side walls 28a as a mask.

The capacitor contact plugs 27a to 27c are thus formed, as illustrated in FIG. 4B. At this time, the capacitor contact plug 27b and the capacitor contact plug 27c are formed isolated from each other. An upper portion of a dummy word line DWL is exposed at the surface of the substrate between the capacitor contact plug 27b and the capacitor contact plug 27c.

Next, as illustrated in FIG. 5A, a capacitor contact isolating and insulating film 29 is formed using a film of a material such as silicon nitride, in such a way as to cover the side walls 28a and the capacitor contact plugs 27a to 27c.

The capacitor contact isolating and insulating film 29, the side walls 28a and the SOD film 25 are then polished by CMP, and the upper surface of the capacitor contact isolating and insulating film 29 is planarized. Upper portions of the capacitor contact plugs 27a to 27c are then etched back, thereby completing the capacitor contact plugs 27a to 27c, as illustrated in FIG. 5B.

Cobalt is then formed on the upper surfaces of the capacitor contact plugs 27a to 27c and the like by sputtering, and heat treatment is performed. By means of the heat treatment, cobalt silicide 37 forms on the upper surfaces of the capacitor contact plugs 27a to 27c in which the polysilicon is exposed, as illustrated in FIG. 5C. The surplus cobalt that has not reacted with the polysilicon is then removed by immersion in concentrated sulfuric acid.

### PATENT LITERATURE

Patent literature article 1: Japanese Patent Kokai 2011-243960

### SUMMARY OF THE INVENTION

### Problems to be Resolved by the Invention

In the construction illustrated in FIG. 1, the resistance of the capacitor contacts is reduced by forming the cobalt silicide on the upper surfaces of the capacitor contact plugs. With this construction, however, if miniaturization progresses and the surface area of the upper surfaces of the capacitor contact plugs decreases, there is a problem in that the surface area of contact between the capacitor contact plugs and the capacitor contact pads, which are connected to the capacitor contact plugs by way of the cobalt silicide, also decreases, and the contact resistance thus increases.

### Means of Overcoming the Problems

A method of manufacturing a semiconductor device in one mode of embodiment comprises: a step of forming a first groove, extending in a prescribed direction, in a first insulating layer on a semiconductor substrate; a step of forming an electrically-conductive embedded layer in the first groove, up to a position that is lower than an upper edge of said first groove; a step of forming side walls covering sidewalls of the first groove, where said sidewalls are exposed above the embedded layer; a step of etching the embedded layer, using the side walls as a mask, to form first and second plugs which separate said embedded layer in the abovementioned prescribed direction; a step of forming a first electrically-conductive film, having a resistance that is lower than the resistance of the embedded layer, on the exposed side surfaces of the first and second plugs; a step of embedding a second insulating layer in a second groove, sandwiched between the first electrically-conductive films of the first and second plugs; a step of removing the side walls after the second insulating layer has been embedded in the second groove; and a step of forming a second electrically-conductive film, having a resistance that is lower than the resistance of the embedded layer, on the exposed upper surfaces of the first and second plugs, after the side walls have been removed.

Further, a semiconductor device in one mode of embodiment comprises: a first insulating layer formed on a semiconductor substrate; a groove provided in the first insulating layer; and first and second plugs disposed sandwiching a second insulating layer in a prescribed direction in the groove, wherein an electrically-conductive film having a resistance that is lower than the resistance of the first and second plugs is provided on the surfaces where the first and second plugs respectively come into contact with the second insulating layer, and on the respective upper surfaces of said first and second plugs.

### Advantages of the Invention

According to the present invention, the low-resistance electrically-conductive film is provided on the upper surfaces of the first and second plugs, and therefore the contact resistance with electrodes that are connected to the plugs is reduced, in addition to which the low-resistance electrically-conductive film is formed on the side surfaces of the plugs, and therefore the resistance of the entire plug can be reduced. Thus even if the contact surface area between the plugs and the pads, which are connected to elements, decreases, an increase in the contact resistance can be suppressed.

### BRIEF EXPLANATION OF THE DRAWINGS

FIG. 1 is a cross-sectional view illustrating one configuration example of a related semiconductor device.

FIG. 2A is a cross-sectional view used to describe a method of manufacturing the related semiconductor device.

FIG. 2B is a cross-sectional view used to describe the method of manufacturing the related semiconductor device.

FIG. 3A is a cross-sectional view used to describe the method of manufacturing the related semiconductor device.

FIG. 3B is a cross-sectional view used to describe the method of manufacturing the related semiconductor device.

FIG. 4A is a cross-sectional view used to describe the method of manufacturing the related semiconductor device.

FIG. 4B is a cross-sectional view used to describe the method of manufacturing the related semiconductor device.

FIG. 5A is a cross-sectional view used to describe the method of manufacturing the related semiconductor device.

FIG. 5B is a cross-sectional view used to describe the method of manufacturing the related semiconductor device.

FIG. 5C is a cross-sectional view used to describe the method of manufacturing the related semiconductor device.

FIG. 6 is a cross-sectional view illustrating a configuration example of a semiconductor device according to this mode embodiment.

FIG. 7A is a cross-sectional view of the semiconductor device illustrated in FIG. 6, corresponding to the part indicated by the line segments Y1-Y2.

FIG. 7B is a cross-sectional view of the semiconductor device illustrated in FIG. 6, corresponding to the part indicated by the line segments X1-X2.

FIG. 8A is a cross-sectional view used to describe a method of manufacturing the semiconductor device in this mode of embodiment.

FIG. 8B is a cross-sectional view used to describe the method of manufacturing the semiconductor device in this mode of embodiment.

FIG. 9A is a cross-sectional view used to describe the method of manufacturing the semiconductor device in this mode of embodiment.

FIG. 9B is a cross-sectional view used to describe the method of manufacturing the semiconductor device in this mode of embodiment.

FIG. 10A is a cross-sectional view used to describe the method of manufacturing the semiconductor device in this mode of embodiment.

FIG. 10B is a cross-sectional view used to describe the method of manufacturing the semiconductor device in this mode of embodiment.

FIG. 11A is a cross-sectional view used to describe the method of manufacturing the semiconductor device in this mode of embodiment.

FIG. 11B is a cross-sectional view used to describe the method of manufacturing the semiconductor device in this mode of embodiment.

FIG. 12A is a cross-sectional view used to describe the method of manufacturing the semiconductor device in this mode of embodiment.

FIG. 12B is a cross-sectional view used to describe the method of manufacturing the semiconductor device in this mode of embodiment.

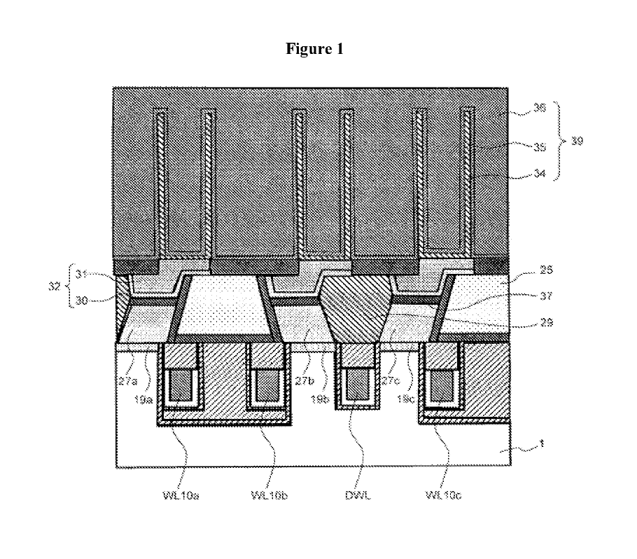

### MODES OF EMBODYING THE INVENTION

The configuration of the semiconductor device in this mode of embodiment will now be described. This mode of embodiment assumes a case in which the semiconductor device is a DRAM.

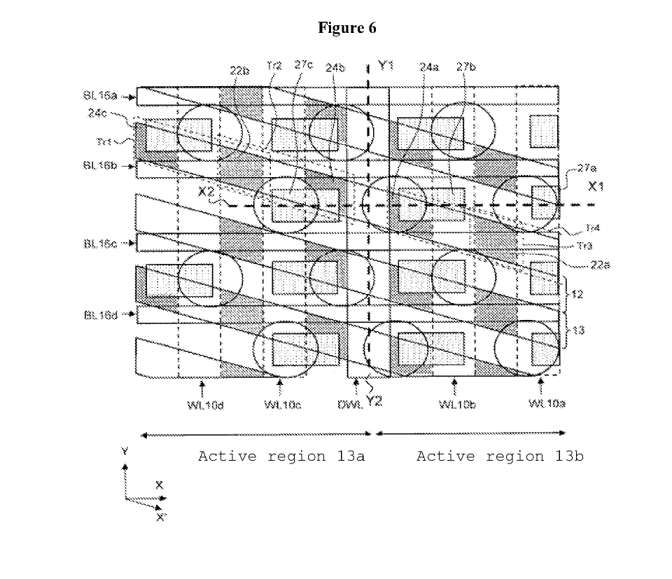

FIG. 6 is a cross-sectional view illustrating a configuration example of a semiconductor device according to this mode embodiment. FIG. 6 illustrates part of a pattern of memory cell arrays. In the plan view illustrated in FIG. 6, the left-right direction is the X-axis direction, the up-down direction is the Y-axis direction, and the longitudinal direction of the pattern of active regions isolated by element isolation regions is the X′-axis direction.

As illustrated in FIG. 6, in a semiconductor substrate 1, element isolation regions 12 extending in the X′-axis direction, and active regions 13, also extending in the X′-axis direction, are disposed alternately at equal intervals and with an equal pitch in the Y-direction. The element isolation regions 12 are formed by an element isolation insulating film which is embedded in a groove.

Embedded word lines (hereinafter referred to as word lines) WL10a to WL10d are disposed extending in the Y-axis direction, straddling a plurality of the element isolation regions 12 and a plurality of the active regions 13. Further, an embedded dummy word line (hereinafter referred to as a dummy word line) DWL is disposed in such a way as to be sandwiched between the word line WL10b and the word line WL10c.

By maintaining parasitic transistors in an OFF state, the dummy word line DWL fulfills the role of isolating cell transistors disposed adjacent to one another in the direction in which the active regions 13 extend, and the role of dividing the strip-shaped active regions 13 into a plurality of independent active regions. In FIG. 6, the strip-shaped active regions located to the left (the negative direction on the X-axis), in the drawing, of the dummy word line DWL are referred to as active regions 13a, and the strip-shaped active regions located to the right (the positive direction on the X-axis), in the drawing, of the dummy word line DWL are referred to as active regions 13b.

The active regions 13a comprise a capacitor contact region 24b disposed adjacent to and on the left of the dummy word line DWL, a word line WL10c disposed adjacent to the capacitor contact region 24b, a bit line contact region 22b disposed adjacent to the word line WL10c, a word line WL10d disposed adjacent to the bit line contact region 22b, and a capacitor contact region 24c disposed adjacent to the word line WL10d.

The active regions 13b comprise a capacitor contact region 24a disposed adjacent to and on the right of the dummy word line DWL, a word line WL10b disposed adjacent to the capacitor contact region 24a, a bit line contact region 22a disposed adjacent to the word line WL10b, a word line WL10a disposed adjacent to the bit line contact region 22a, and a capacitor contact region (which is not shown in the drawing) disposed adjacent to the word line WL10a.

A description will now be given of the cell transistors which are connected to capacitors for accumulating information. The cell transistors are configured from MOS transistors, and here the configuration of four cell transistors Tr1 to Tr4 illustrated in FIG. 6 will be described.

The cell transistor Tr1 has a configuration comprising the capacitor contact region 24c, the word line WL10d and the bit line contact region 22b. The cell transistor Tr2 has a configuration comprising the bit line contact region 22b, the word line WL10c and the capacitor contact region 24b.

The cell transistor Tr3 has a configuration comprising the capacitor contact region 24a, the word line WL10b and the bit line contact region 22a. The cell transistor Tr4 has a configuration comprising the bit line contact region 22a, the word line WL10a and a capacitor contact region (which is not shown in the drawing).

In the memory cell array region of the semiconductor device in this mode of embodiment, a plurality of the configurations described with reference to the active region 13a and the active region 13b are disposed in the X-axis direction, with the interposition of the dummy word lines DWL.

The cross-sectional structure of the semiconductor device illustrated in FIG. 6 will now be described.

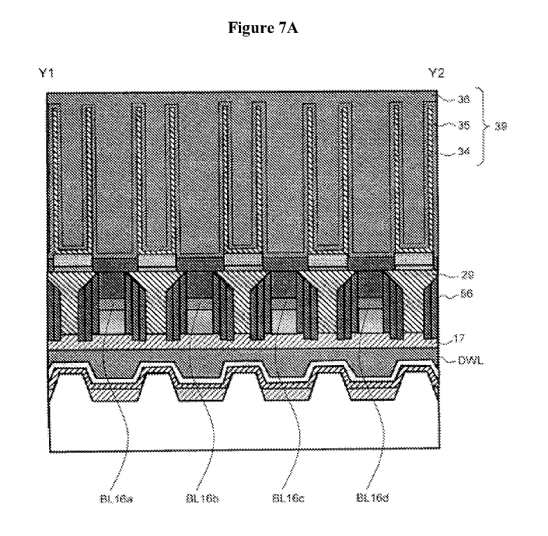

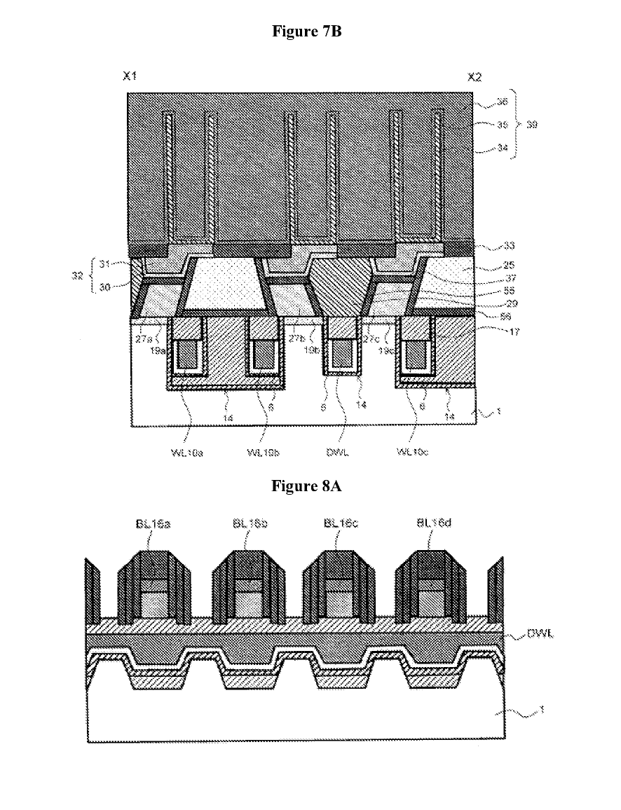

FIG. 7A and FIG. 7B are cross-sectional views illustrating one configuration example of the semiconductor device illustrated in FIG. 6. FIG. 7A illustrates the cross-sectional structure corresponding to the part indicated by the line segments Y1-Y2 illustrated in FIG. 6, and FIG. 7B illustrates the cross-sectional structure corresponding to the part indicated by the line segments X1-X2 illustrated in FIG. 6.

As illustrated in FIG. 7B, grooves 14 for word lines, which also serve as the cell transistor gate electrodes, and for the dummy word line, are provided in the semiconductor substrate 1. The word lines WL10a to 10c and the dummy word line DWL are provided in the vicinity of the bottom portions of the grooves, with the interposition of gate insulating films 6 covering the inner surfaces of each of the grooves 14 for the word lines and for the dummy word line. Cap insulating films 17 are embedded in the grooves 14, covering the word lines WL10a to WL10c and the dummy word line DWL.

The semiconductor pillar located to the left, in the drawing, of the word line WL10a, corresponds to a capacitor contact region (which is not shown in the drawing). An impurity-diffused layer 19a which forms either a source electrode or a drain electrode of a cell transistor (which is not shown in the drawing) is provided on the upper surface of the substrate in this capacitor contact region.

Further, the semiconductor pillar located to the right, in the drawing, of the word line WL10b, corresponds to the capacitor contact region 24a illustrated in FIG. 6. An impurity-diffused layer 19b which forms either the source electrode or the drain electrode of the cell transistor Tr3 is provided on the upper surface of the substrate in the capacitor contact region 24a.

Further, the semiconductor pillar located to the left, in the drawing, of the word line WL10c, corresponds to the capacitor contact region 24b illustrated in FIG. 6. An impurity-diffused layer 19c which forms either the source electrode or the drain electrode of the cell transistor Tr2 is provided on the upper surface of the substrate in the capacitor contact region 24b.

As illustrated in FIG. 7A, a liner insulating film 56 is provided over the entire surface of the cap insulating film 17 in such a way as to cover the sidewalls of bit lines BL16a to BL16d. A capacitor contact isolating and insulating film 29 is provided on the liner insulating film 56 in such a way as to fill the recessed spaces formed between adjacent bit lines.

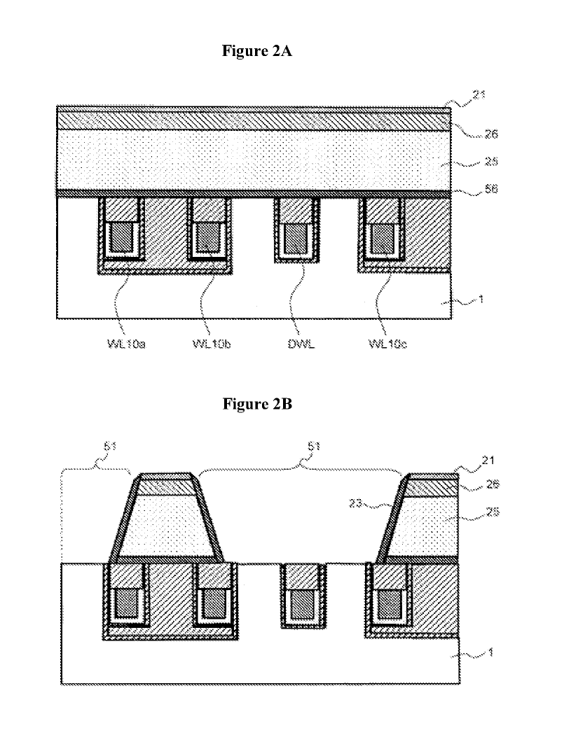

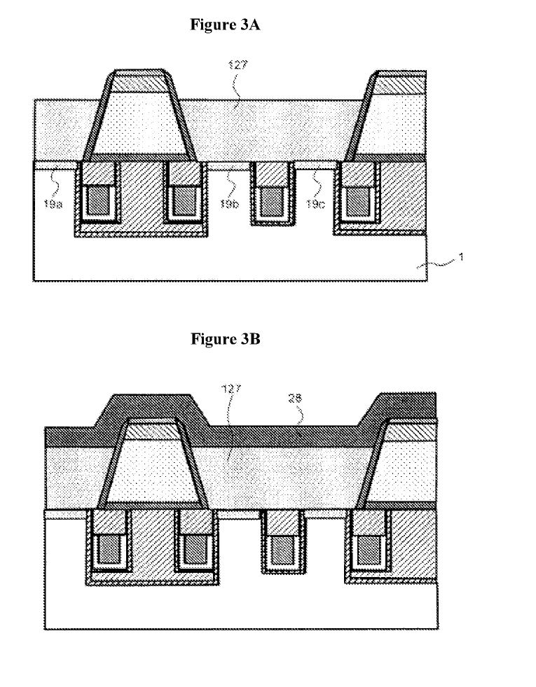

The capacitor contact holes 51 illustrated in FIG. 2B are formed in the SOD film 25, and the capacitor contact plugs 27a to 27c are provided in the capacitor contact holes 51 illustrated in FIG. 2B, as illustrated in FIG. 7B.

The capacitor contact plugs 27b and 27c are connected to the impurity-diffused layers 19b and 19c formed in the capacitor contact regions 24a and 24b illustrated in FIG. 6, and the capacitor contact plug 27a is connected to the impurity-diffused layer 19a. The capacitor contact plugs 27b and 27c are disposed in the same capacitor contact hole, sandwiching the capacitor contact isolating and insulating film 29.

Cobalt silicide 55 having a resistance that is lower than the resistance of the capacitor contact plugs 27a to 27c is formed on the side surfaces of said plugs. Further, cobalt silicide 37 is formed on the upper surfaces of the capacitor contact plugs 27a to 27c. Capacitative contact pads 32 are connected by way of the cobalt silicide 37 to each of the capacitative contact plugs 27a to 27c.

Stopper films 33 are provided in such a way as to cover the side surfaces of the capacitor contact pads 32. The capacitor contact pads 32 are connected to lower electrodes 34 of capacitors 39. The capacitors 39 have a configuration comprising the lower electrode 34, a capacitative insulating film 35 covering the outer surfaces of the lower electrode 34, and an upper electrode 36 provided on the capacitative insulating film 35.

In the semiconductor device of this mode of embodiment, not only is the cobalt silicide 37 formed on the upper surfaces of the capacitor contact plugs, but in addition the cobalt silicide 55 is also formed on the side surfaces of the capacitor contact plugs, and therefore the construction is such that the resistance of the entire capacitor contact plug is reduced.

By means of the cobalt silicide 37 provided on the upper surfaces of the capacitor contact plugs, the contact resistance between the capacitor contact plugs and the capacitor contact pads is reduced, in addition to which the cobalt silicide 55 provided on the side surfaces of the capacitor contact plugs is in contact with the capacitor contact pads by way of the cobalt silicide 37. The contact resistance from the impurity-diffused layer formed in the vicinity of the substrate surface to the capacitor contact pad, by way of the capacitor contact plug, can therefore be reduced.

As a result, even if the contact surface area between the capacitor contact plugs and the capacitor contact pads, connected to the capacitor elements, decreases as miniaturization progresses, an increase in the contact resistance can be suppressed.

A method of manufacturing the semiconductor device in this mode of embodiment will now be described.

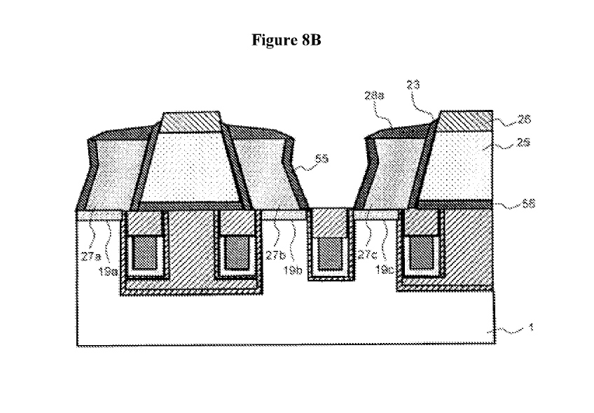

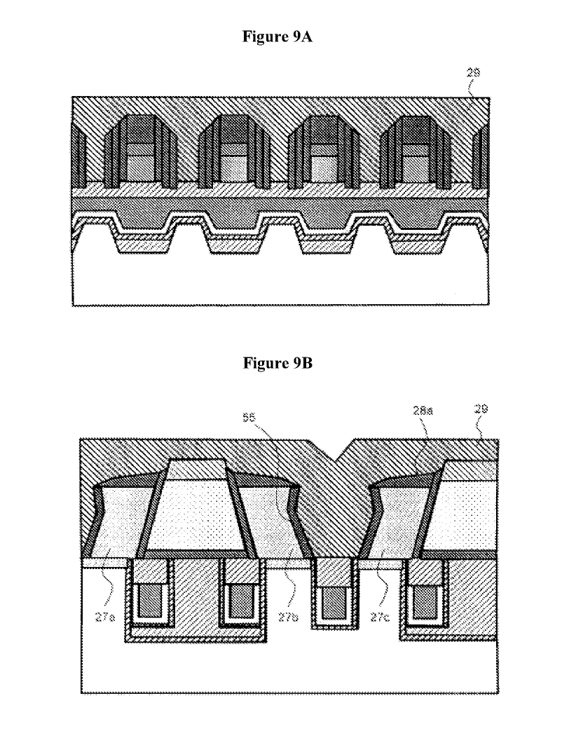

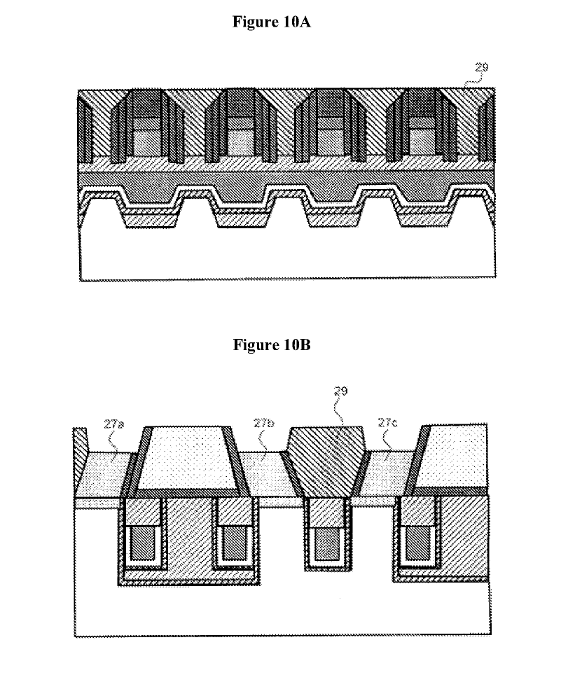

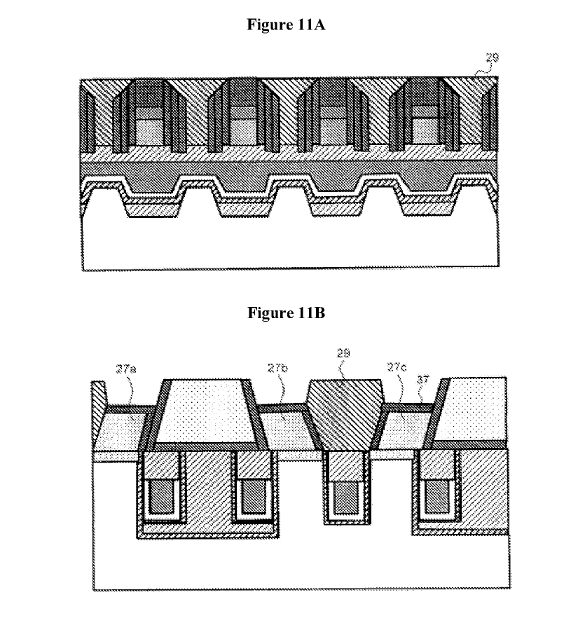

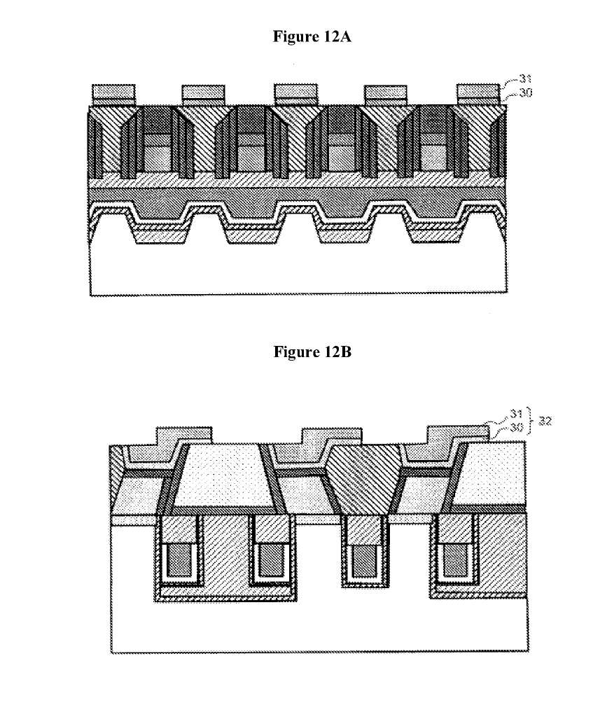

FIG. 8A to FIG. 12B are cross-sectional views used to describe the method of manufacturing the semiconductor device in this mode of embodiment. The cross-sectional views in FIG. 8A, FIG. 9A, FIG. 10A, FIG. 11A and FIG. 12A each correspond to the part indicated by the line segment Y1-Y2 illustrated in FIG. 6. The cross-sectional views in FIG. 8B, FIG. 9B, FIG. 10B, FIG. 11B and FIG. 12B each correspond to the part indicated by the line segment X1-X2 illustrated in FIG. 6.

Here, a detailed description of steps that are the same as in the method of manufacturing the related semiconductor device is omitted. Further, the cross-sectional structure of the part indicated by the line segment X1-X2 relating to the twin plug is described in detail, but a detailed description relating to the cross-sectional structure of the part indicated by the line segment Y1-Y2 is omitted.

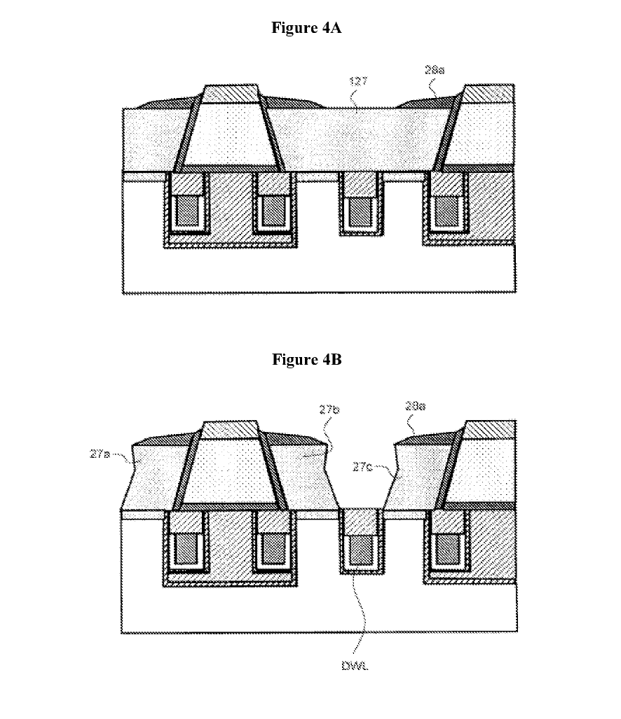

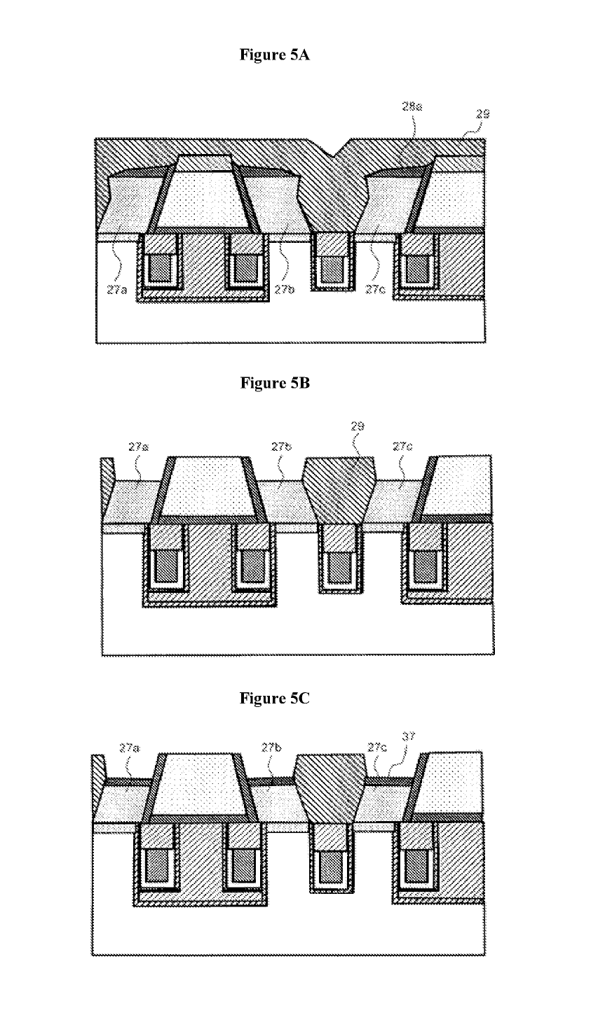

After the step described with reference to FIG. 4B, cobalt is formed on the side surfaces of the capacitor contact plugs 27a to 27c and the like by sputtering, and heat treatment is performed. By means of the heat treatment, cobalt silicide 55 forms on the side surfaces of the capacitor contact plugs 27a to 27c in which the polysilicon is exposed, as illustrated in FIG. 8B. The surplus cobalt that has not reacted with the polysilicon is then removed by immersion in concentrated sulfuric acid.

As illustrated in FIG. 2B, the cross-sectional structure of the capacitative contact hole 51 is an inverted tapered shape in which the length in the X-axis direction (see FIG. 6) increases from a lower portion to an upper portion, and therefore, as illustrated in FIG. 4B, the side surfaces of the capacitative contact plugs 27a to 27c are inclined from the vertical direction. Thus when the cobalt is formed by sputtering, a cobalt film can be formed on the side surfaces of the capacitative contact plugs 27a to 27c in such a way as to have a uniform film thickness. It should be noted that the metal film is not limited to being cobalt, and may be another metal film. Further, the method of forming the metal film is not limited to sputtering, and another method such as CVD may also be used.

Next, as illustrated in FIG. 9B, a capacitor contact isolating and insulating film 29 is formed in such a way as to cover the cobalt silicide 55 and the like on the side walls 28a and on the side surfaces of the capacitative contact plugs 27a to 27c, illustrated in FIG. 8B. At this time, the capacitor contact isolating and insulating film 29 fills the grooves provided in the spaces sandwiched between the cobalt silicide 55 on the capacitor contact plug 27b and the capacitor contact plug 27c.

The capacitor contact isolating and insulating film 29, the side walls 28a and the SOD film 25 are then polished by CMP, and the upper surface of the capacitor contact isolating and insulating film 29 is planarized. Upper portions of the capacitor contact plugs 27a to 27c are then etched back, thereby completing the capacitor contact plugs 27a to 27c, as illustrated in FIG. 10B.

In this mode of embodiment, the upper portions of the capacitor contact plugs 27a to 27c are etched back to make the upper surfaces of these plugs lower than the upper surface of the capacitor contact isolating and insulating film 29. Recesses are thus formed, but the recesses are formed in order for the capacitor contact pads 32, formed in a later step, to be formed with a limited surface area, and the upper surfaces of the capacitor contact plugs 27a to 27c may be made to coincide with the upper surface of the capacitor contact isolating and insulating film 29.

Cobalt is then formed on the upper surfaces of the capacitor contact plugs 27a to 27c and the like by sputtering, and heat treatment is performed. By means of the heat treatment, cobalt silicide 37 forms on the upper surfaces of the capacitor contact plugs 27a to 27c in which the polysilicon is exposed, as illustrated in FIG. 11B. The surplus cobalt that has not reacted with the polysilicon is then removed by immersion in concentrated sulfuric acid.

A wiring-line material layer comprising titanium nitride 30, tungsten 31 and the like is then formed on the upper surface of the cobalt silicide 37 by CVD, these films being embedded in the abovementioned recesses. Etching and photolithography are then used to form the capacitor contact pads 32, as illustrated in FIG. 12B. Subsequent steps are the same as in patent literature article 1, and are therefore described simply, with reference to FIG. 7B.

A stopper film 33 is formed using a silicon nitride film in such a way as to cover the capacitor contact pads 32. Lower electrodes 34 of capacitors 39 are formed on the capacitative contact pads 32 using titanium nitride or the like. A capacitative insulating film 35 is then formed in such a way as to cover the surfaces of the lower electrodes 34, after which upper electrodes 36 of the capacitors 39 are formed using titanium nitride or the like. Although not shown in the drawing, multilayer wiring lines are formed by repeating the wiring-line forming steps, thereby completing the semiconductor device.

In the method of manufacturing a semiconductor device in this mode of embodiment, the resistance of the capacitative contacts can be reduced simply by adding the step of forming the cobalt silicide on the side surfaces of the capacitative contact plugs, after the capacitor contact plugs have been formed by etching the polysilicon plugs using the side walls as a mask.

Further, by forming the capacitor contact grooves with an inverted tapered shape, the side surfaces of the capacitative contact plugs are formed at an incline to the vertical direction, and the metal film can therefore be formed on the side surfaces in such a way as to have a uniform film thickness. As a result, the metal silicide after siliciding can also be formed having a uniform film thickness.

It should be noted that the present invention is not limited to the abovementioned modes of embodiment, and various modifications may be made within the scope of the invention, and it goes without saying that these are also included within the scope of the present invention.

### EXPLANATION OF THE REFERENCE NUMBERS

27a to 27c Capacitor contact plug

29 Capacitor contact isolating and insulating film

37, 55 Cobalt silicide

51 Capacitor contact hole

127 Polysilicon plug

1. A method of manufacturing a semiconductor device, comprising:
forming a first groove, extending in a prescribed direction, in a first insulating layer on a semiconductor substrate;
forming an electrically-conductive embedded layer in the first groove, up to a position that is lower than an upper edge of said first groove;
forming side walls covering sidewalls of the first groove, where said sidewalls are exposed above the embedded layer;
etching the embedded layer, using the side walls as a mask, to form first and second plugs which separate said embedded layer in the abovementioned prescribed direction;
forming a first electrically-conductive film, having a resistance that is lower than the resistance of the embedded layer, on the exposed side surfaces of the first and second plugs;
embedding a second insulating layer in a second groove, sandwiched between the first electrically-conductive films of the first and second plugs;
removing the side walls after the second insulating layer has been embedded in the second groove; and
forming a second electrically-conductive film, having a resistance that is lower than the resistance of the embedded layer, on the exposed upper surfaces of the first and second plugs, after the side walls have been removed.

2. The method of claim 1, wherein forming the embedded layer comprises forming a polysilicon film doped with an electrically-conductive impurity, and forming the first and second electrically-conductive films comprises forming a metal film, and siliciding said metal film.

3. The method of claim 1, wherein forming the first groove comprises forming said first groove in such a way that the length of said first groove in the abovementioned prescribed direction increases from its bottom portion to its upper portion.

4. A semiconductor device comprising:
a first insulating layer formed on a semiconductor substrate;
a groove provided in the first insulating layer; and
first and second plugs disposed sandwiching a second insulating layer in a prescribed direction in the groove, wherein an electrically-conductive film having a resistance that is lower than the resistance of the first and second plugs is provided on the surfaces where the first and second plugs respectively come into contact with the second insulating layer, and on the respective upper surfaces of said first and second plugs.

5. The semiconductor device of claim 4, wherein the first and second plugs are formed from a polysilicon film doped with an electrically-conductive impurity, and the electrically-conductive film is a metal silicide film.

6. The semiconductor device of claim 4, wherein the length of the first groove in the abovementioned prescribed direction increases from its bottom portion to its upper portion.
